(19) United States
(12) Patent Application Publication
(10) Pub. No.: US 2026/0297740 A1
(43) Pub. Date: Oct. 1, 2026

(54) SUBSTRATE PROCESSING METHOD, METHOD OF MANUFACTURING SEMICONDUCTOR DEVICE, NON-TRANSITORY COMPUTER-READABLE RECORDING MEDIUM AND SUBSTRATE PROCESSING APPARATUS

(71) Applicant: Kokusai Electric Corporation, Tokyo (JP)

(72) Inventors: Shingo NOHARA, Toyama-shi (JP); Yoma YAMANE, Toyama-shi (JP); Shinya EBATA, Toyama-shi (JP)

(73) Assignee: Kokusai Electric Corporation, Tokyo (JP)

(21) Appl. No.: 19/459,042

(22) Filed: Jan. 26, 2026

(30) Foreign Application Priority Data
Mar. 26, 2025 (JP) 2025-051341

(51) Int. Cl. C23C 16/44

(52) U.S. Cl. CPC C23C 16/4412; C23C 16/4408

(57) ABSTRACT

It is possible to suppress an adhesion of foreign matters (or particles) to a substrate. There is provided a technique that includes: (a) performing: (a1) supplying a process gas to a substrate arranged in a process chamber through a supplier; and (a2) exhausting a gas in the process chamber through a main exhaust path configured to connect the process chamber to an exhaust apparatus; and (b) exhausting a predetermined gas in the supplier through a subsidiary exhaust path configured to connect the supplier to the main exhaust path without passing through the process chamber, while suppressing or blocking a gas flow from the main exhaust path to the process chamber.

### CROSS-REFERENCE TO RELATED PATENT APPLICATION

This non-provisional U.S. patent application is based on and claims priority under 35 U.S.C. § 119 of Japanese Patent Application No. 2025-051341, filed on Mar. 26, 2025, in the Japanese Patent Office, the entire contents of which are hereby incorporated by reference.

### BACKGROUND

### 1. Field

The present disclosure relates to a substrate processing method, a method of manufacturing a semiconductor device, a non-transitory computer-readable recording medium and a substrate processing apparatus.

### 2. Related Art

According to some related arts, as a part of a manufacturing process of a semiconductor device or a part of a substrate processing, a process gas stored in a storage (also referred to as a “reservoir”) may be supplied to a substrate.

### SUMMARY

According to the present disclosure, there is provided a technique capable of suppressing an adhesion of foreign matters (or particles) to a substrate.

According to an embodiment of the present disclosure, there is provided a technique that includes: (a) performing: (a1) supplying a process gas to a substrate arranged in a process chamber through a supplier; and (a2) exhausting a gas in the process chamber through a main exhaust path configured to connect the process chamber to an exhaust apparatus; and (b) exhausting a predetermined gas in the supplier through a subsidiary exhaust path configured to connect the supplier to the main exhaust path without passing through the process chamber, while suppressing or blocking a gas flow from the main exhaust path to the process chamber.

### BRIEF DESCRIPTION OF THE DRAWINGS

FIG. 1 is a diagram schematically illustrating a vertical cross-section of a substrate processing apparatus according to one or more embodiments of the present disclosure.

FIG. 2A is a diagram schematically illustrating a first process gas supplier according to the embodiments of the present disclosure, FIG. 2B is a diagram schematically illustrating a second process gas supplier according to the embodiments of the present disclosure, and FIG. 2C is a diagram schematically illustrating an exhauster according to the embodiments of the present disclosure.

FIG. 3 is a block diagram schematically illustrating a configuration of a controller and its related components of the substrate processing apparatus according to the embodiments of the present disclosure.

FIG. 4A is a flow chart schematically illustrating a substrate processing according to the embodiments of the present disclosure, FIG. 4B is a flow chart schematically illustrating a preparation step according to the embodiments of the present disclosure, FIG. 4C is a flow chart schematically illustrating a processing step according to the embodiments of the present disclosure, and FIG. 4D is a flow chart schematically illustrating a first process gas supply step according to the embodiments of the present disclosure.

### DETAILED DESCRIPTION

### Embodiments of Present Disclosure

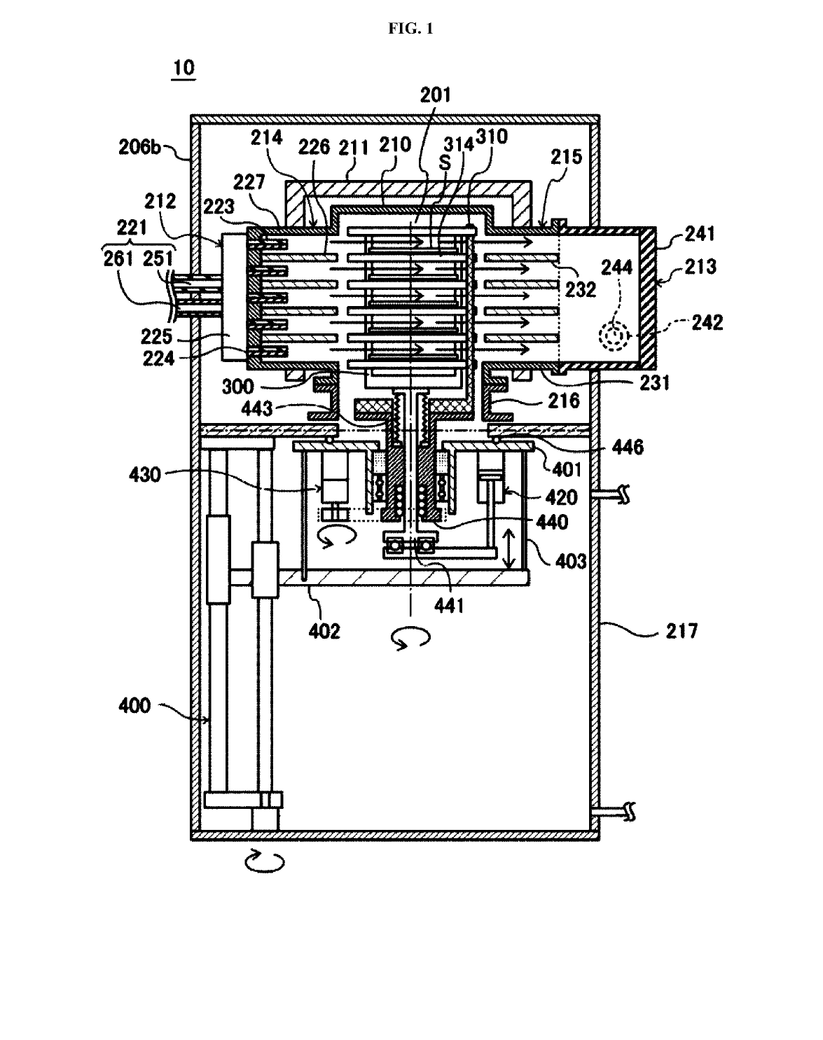

Hereinafter, one or more embodiments (also simply referred to as “embodiments”) according to the technique of the present disclosure will be described mainly with reference to FIGS. 1-4D. The drawings used in the following descriptions are all schematic. For example, a relationship between dimensions of each component and a ratio of each component shown in the drawing may not always match the actual ones. Further, even between the drawings, the relationship between the dimensions of each component and the ratio of each component may not always match.

### (1) Configuration of Substrate Processing Apparatus

A configuration of a substrate processing apparatus 10 according to the present embodiments will be described with reference to FIG. 1.

The substrate processing apparatus 10 includes a reaction tube storage chamber 206b. In the reaction tube storage chamber 206b, a reaction tube 210, a heater 211 serving as a heating structure (furnace structure) installed on an outer periphery of the reaction tube 210, a gas supply structure 212 serving as a part of a gas supplier (which is a gas supply system), and a gas exhaust structure 213 serving as a part of a gas exhauster (which is a gas exhaust system) are provided. The gas supplier may further include an upstream side gas guide 214, a plurality of nozzles 223 and a plurality of nozzles 224, which will be described later. In addition, the gas exhauster may further include a downstream side gas guide 215, which will be described later. In the reaction tube 210, a portion in which a plurality of substrates S are processed may also be referred to as a “process chamber 201”. Hereinafter, each of the plurality of substrates S may also be referred to as a “substrate S”. In addition, the process chamber 201 may also be referred to as a “process space” in which the substrates S are arranged (disposed or placed).

A gas supplied into the reaction tube 210 through the gas supply structure 212 moves in a horizontal direction relative to the substrate S, and is discharged (exhausted) through the gas exhaust structure 213. The upstream side gas guide 214 is provided between the reaction tube 210 and the gas supply structure 212. In addition, the downstream side gas guide 215 is provided between the reaction tube 210 and the gas exhaust structure 213. A lower end of the reaction tube 210 is supported by a manifold 216. A heat from the heater 211 heats the substrate S and the gas in the process chamber 201.

The gas supply structure 212 is connected to each of a gas supply pipe 251 and a gas supply pipe 261, and includes a distribution structure (also referred to as a “distributor”) 225 configured to distribute gases supplied through each gas supply pipe described above. The nozzles 223 and the nozzles 224 are provided at a downstream side of the distribution structure 225. In the present embodiments, the gas supply pipe 251 and the gas supply pipe 261 may also be collectively or individually referred to as a “gas supply pipe 221”. In addition, each of the nozzles 223 may also be referred to as a “nozzle 223”, and each of the nozzles 224 may also be referred to as a “nozzle 224”. Each of the nozzles 223 and 224 may also be referred to as a “gas ejection structure”. The distribution structure 225 is configured such that each gas can be supplied to the nozzles 223 through the gas supply pipe 251 and to the nozzles 224 through the gas supply pipe 261. The upstream side gas guide 214 includes a housing 227 and a plurality of partition plates 226. Hereinafter, each of the partition plates 226 may also be referred to as a “partition plate 226”. The nozzle 223 and the nozzle 224 are arranged between adjacent partition plates among the partition plates 226 or between the partition plate 226 and the housing 227. The downstream side gas guide 215 includes a housing 231 and a plurality of partition plates 232. Hereinafter, each of the partition plates 232 may also be referred to as a “partition plate 232”. The gas exhaust structure 213 is constituted mainly by a housing 241, an exhaust pipe connection structure 242 and an exhaust hole 244.

A transfer chamber 217 is provided (or formed) below the reaction tube 210. An operation of transferring the substrate S into or out of the transfer chamber 217 may be performed by a transfer robot (not shown) through a substrate loading/unloading port (not shown), and an operation of placing (or charging) the substrate S on a substrate support 300 in the transfer chamber 217 or taking out (or discharging) the substrate S from the substrate support 300 in the transfer chamber 217 may be performed. Hereinafter, the substrate support 300 may also be simply referred to as a “boat 300”.

A vertical driver (which is a vertical direction driving structure) 400 is configured to move the substrate support 300 and a partition plate support 310 in an up-down direction (vertical direction) between the reaction tube 210 and the transfer chamber 217. For example, FIG. 1 shows a state in which the substrate support 300 and the partition plate support 310 are elevated by the vertical driver 400 and stored in the reaction tube 210. The vertical driver 400 may include: a rotational driver (which is a rotational driving structure) 430 configured to rotate the substrate support 300 and the partition plate support 310 together; and a boat vertical driver (which is a boat vertical driving structure) 420 configured to drive the substrate support 300 in the vertical direction relative to the partition plate support 310. The rotational driver 430 and the boat vertical driver 420 are fixed to a base flange 401 serving as a lid supported by a side plate 403 on a base plate 402. An O-ring 446 for a vacuum seal is installed on an upper surface of the base flange 401. A support structure 440 fixed to the partition plate support 310 and a support 441 fixed to the substrate support 300 are connected by a vacuum bellows 443.

The plurality of substrates S are placed on the substrate support 300 at a predetermined interval therebetween in the vertical direction (up-down direction). A plurality of partition plates 314 are arranged on the partition plate support 310. Hereinafter, each of the partition plates 314 may also be referred to as a “partition plate 314”. The partition plates 314 may be provided directly below the substrates S, respectively. For example, the partition plates 314 may be provided above or below the substrates S, respectively. For example, adjacent partition plates among the partition plates 314 may be provided above and below the substrate S. It is preferable that, in a substrate processing described later, the partition plate 314, the partition plate 226 corresponding to the partition plate 314 and the partition plate 232 corresponding to the partition plate 314 are provided at the same height. With such a configuration, it is possible to easily form a horizontal gas flow passing over the partition plate 226, the substrate S corresponding to the partition plate 226 and the partition plate 232 corresponding to the partition plate 226, while suppressing a vertical gas flow. Thereby, it is possible to uniformly process the substrates S.

In addition, FIG. 1 shows an example in which five substrates are supported by the substrate support 300. However, the present embodiments are not limited thereto. For example, the substrate support 300 may be configured to support from 5 substrates to 50 substrates as the substrates S. In addition, in the present specification, a notation of a numerical range such as “from 5 substrates to 50 substrates” means that a lower limit and an upper limit are included in the numerical range. Therefore, for example, a numerical range “from 5 substrates to 50 substrates” means a range equal to or more than 5 substrates and equal to or less than 50 substrates. The same also applies to other numerical ranges described in the present specification.

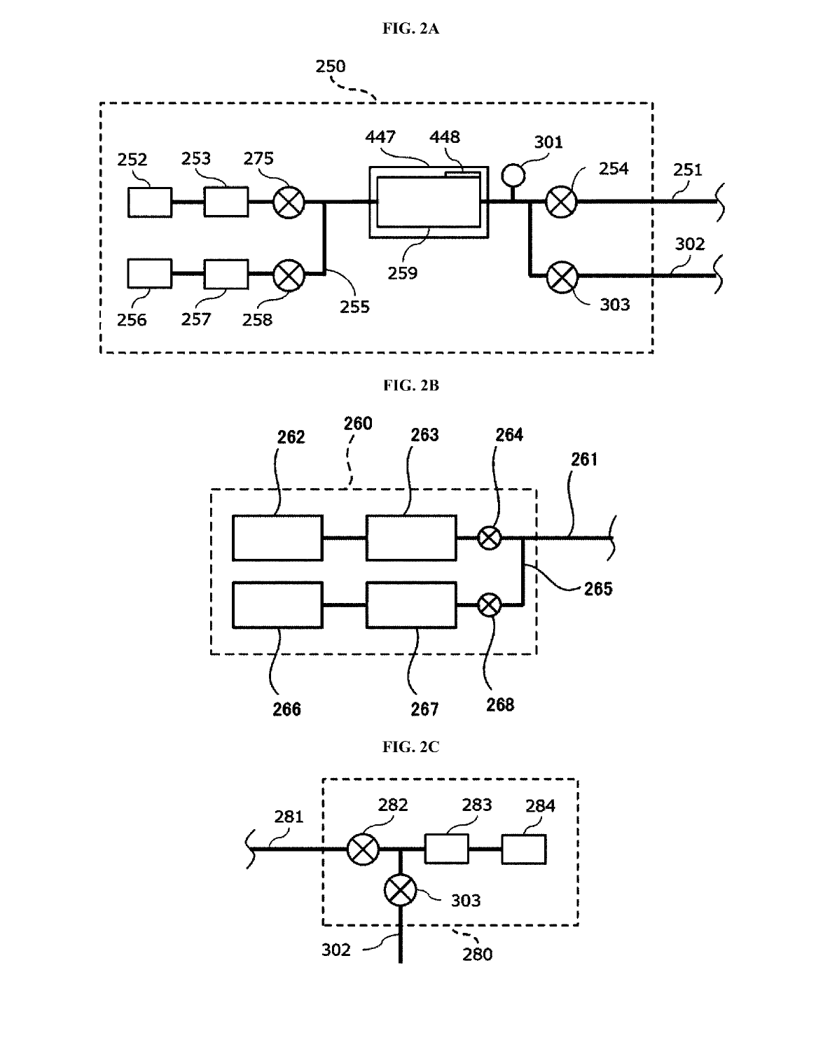

As shown in FIG. 2A, a first process gas supply source 252, a mass flow controller (MFC) 253 serving as a flow rate controller (a flow rate control structure), a valve 275 serving as an opening/closing valve, a tank 259 serving as a storage (reservoir) configured to store the gas (such as a first process gas) therein, a sensor 301 serving as a pressure measuring structure (pressure meter) configured to measure a pressure (inner pressure) of the tank 259 and a valve 254 are sequentially installed at the gas supply pipe 251 in this order from an upstream side to a downstream side of the gas supply pipe 251 in a gas flow direction. An exhaust pipe 302 is connected to the gas supply pipe 251 between the sensor 301 and the valve 254. The exhaust pipe 302 serves as a subsidiary exhaust path (secondary exhaust path) through which the gas in the tank 259 is exhausted without passing through the process chamber 201. A valve 303 is provided at the exhaust pipe 302. The first process gas serves as one of process gases in the embodiments of the present disclosure. Hereinafter, each of the process gases may also be referred to as a “process gas”.

A sensor 448 serving as a temperature measuring structure (temperature meter) is provided at the tank 259. The sensor 448 is configured to measure a temperature (inner temperature) of the tank 259 and/or a temperature of the gas (such as the first process gas) stored in the tank 259. In addition, a heater 447 serving as a heating structure (temperature controller) is provided at the tank 259. The heater 447 is configured to regulate (or adjust) the inner temperature of the tank 259 and/or the temperature of the gas stored in the tank 259. According to the present embodiments, for example, instead of or in addition to the tank 259, a structure such as a spiral pipe and a portion of the gas supply pipe 251 (whose diameter is greater than an upstream portion and a downstream portion of the gas supply pipe 251) may be used as the storage. By opening and closing the valve 275 on the upstream side of the tank 259 and the valve 254 on the downstream side of the tank 259, it is possible to temporarily store (fill) the gas supplied through the gas supply pipe 251 in the tank 259, and it is also possible to supply the gas stored in the tank 259 into the process chamber 201.

According to the present embodiments, for example, when a measurement point is provided between an outer wall of the tank 259 and the heater 447, it may not be possible to measure the inner temperature of the tank 259 (for example, one or more among a temperature of an inner wall of the tank 259 and the temperature of the gas inside the tank 259) or it may not be possible to measure a change in the inner temperature of the tank 259 over time in detail and/or accurately. That is, depending on conditions under which the sensor 448 measures the temperature mentioned above, an actual temperature inside the tank 259 may be changing even when a measurement result of the sensor 448 does not indicate the change in the temperature.

The first process gas supply source 252 is a source of the first process gas (also referred to as a “source gas”), that is, a gas whose phase may change to a liquid or a solid due to a decrease in a temperature before being supplied to the process chamber 201. As the first process gas supply source 252, for example, a vaporizer configured to generate the first process gas by changing a phase of a liquid substance or a solid substance may be used, or an introduction port (which is an inlet) through which the first process gas is supplied from outside the substrate processing apparatus 10 may be used. Hereinafter, the present embodiments will be described by way of an example in which a gas obtained by vaporizing a liquid substance or a solid substance at a room temperature and a normal pressure is used as the first process gas. The first process gas may also serve as a predetermined gas (specified gas), as described below.

A first process gas supplier (which is a first process gas supply system) 250 is constituted mainly by the gas supply pipe 251, the MFC 253, the valve 275, the tank 259, the sensor 301 and the valve 254. The first process gas supplier 250 may also be referred to as a “source gas supplier 250” which is a source gas supply system. The first process gas supplier 250 may further include the first process gas supply source 252. In addition, the first process gas supplier 250 may further include the sensor 448 and the heater 447. In addition, the first process gas supplier 250 may further include the valve 303. For example, a heater (not shown) other than the heater 447 may be provided in each component of the first process gas supplier 250 to adjust a temperature of the first process gas supplier 250.

A gas supply pipe 255 is connected to the gas supply pipe 251 between the valve 275 and the tank 259. An inert gas supply source 256, an MFC 257 and a valve 258 are sequentially installed at the gas supply pipe 255 in this order from an upstream side to a downstream side of the gas supply pipe 255 in the gas flow direction. For example, an inert gas is supplied from the inert gas supply source 256. A first inert gas supplier (which is a first inert gas supply system) is constituted mainly by the gas supply pipe 255, the MFC 257 and the valve 258. The first inert gas supplier may further include the inert gas supply source 256. In addition, the first process gas supplier 250 may further include the first inert gas supplier. In the present specification, the inert gas may act as a purge gas for purging an inside (inner portion) of the first process gas supplier 250 or an inside (inner portion) of the process chamber 201, may act as a dilution gas for diluting the first process gas, or may act as a carrier gas supplied simultaneously with the first process gas.

The first process gas supplier 250 is an example of a supplier (which is a supply system) configured to control a gas circulation between the first process gas supply source 252 (which is a supply source of the process gas (predetermined gas)) and the process chamber 201 (which is the space in which the substrates S are arranged). For example, as a control of the flow of the gas, the first process gas supplier 250 is configured to control whether or not the gas (for example, the first process gas and/or the inert gas) can flow through each component of the first process gas supplier 250, to control a flow rate of the gas passing through each component of the first process gas supplier 250, and to control the temperature of the gas at each component of the first process gas supplier 250.

As the inert gas, for example, a gas such as nitrogen (N₂) gas and a rare gas may be used. As the rare gas, for example, a gas such as helium (He) gas, argon (Ar) gas, neon (Ne) gas and xenon (Xe) gas may be used. For example, one or more of the gases exemplified above may be used as the inert gas.

As shown in FIG. 2B, a second process gas supply source 262, an MFC 263 and a valve 264 are sequentially installed at the gas supply pipe 261 in this order from an upstream side to a downstream side of the gas supply pipe 261 in the gas flow direction. The second process gas supply source 262 is a source of a second process gas (also referred to as a “reactive gas”). The second process gas serves as one of the process gases. A second process gas supplier (which is a second process gas supply system) 260 is constituted mainly by the gas supply pipe 261, the MFC 263 and the valve 264. The second process gas supplier 260 may also be referred to as a “reactive gas supplier 260” which is a reactive gas supply system. The second process gas supplier 260 may further include the second process gas supply source 262.

A gas supply pipe 265 is connected to the gas supply pipe 261 at a downstream side of the valve 264. An inert gas supply source 266, an MFC 267 and a valve 268 are sequentially installed at the gas supply pipe 265 in this order from an upstream side to a downstream side of the gas supply pipe 265 in the gas flow direction. The inert gas is supplied from the inert gas supply source 266. A second inert gas supplier (which is a second inert gas supply system) is constituted mainly by the gas supply pipe 265, the MFC 267 and the valve 268. The second inert gas supplier may further include the inert gas supply source 266. The second process gas supplier 260 may further include the second inert gas supplier.

As shown in FIG. 2C, a vacuum pump 284 serving as an exhaust apparatus is connected to an exhaust pipe 281 via a valve 282, the exhaust pipe 302 and an APC (Automatic Pressure Controller) valve 283 serving as a pressure regulator (which is a pressure adjusting structure), in this order from the reaction tube 210. As described above, the valve 303 is provided at the exhaust pipe 302. For example, the APC valve 283 is a butterfly valve. The exhaust pipe 281 is connected to the exhaust pipe connection structure 242.

According to the present embodiments, the exhaust pipe 281 serves as an example of a main exhaust path (primary exhaust path) configured to connect the process chamber 201 and the vacuum pump 284. In addition, the exhaust pipe 302 serves as an example of the subsidiary exhaust path configured to connect the supplier to the exhaust pipe 281 (which serves as the main exhaust path) without passing through the process chamber 201. In addition, the valve 282 serves as an example of a predetermined structure configured to suppress or block the flow of the gas from the main exhaust path to the process chamber 201.

With the vacuum pump 284 in operation, by opening the valve 282 and controlling an opening degree of the APC valve 283, it is possible to vacuum-exhaust (or evacuate) the reaction tube 210 such that a pressure (inner pressure) of the reaction tube 210 reaches and is maintained at a predetermined pressure (vacuum degree). In addition, with the vacuum pump 284 in operation, by opening the valve 303, it is possible to exhaust the inside of the first process gas supplier 250. An exhauster (which is an exhaust system) 280 is constituted mainly by the exhaust pipe 281, the valve 282, the APC valve 283 and the valve 303. The exhauster 280 may also be referred to as a “process chamber exhauster” which is a process chamber exhaust system. For example, the exhauster 280 may further include the vacuum pump 284.

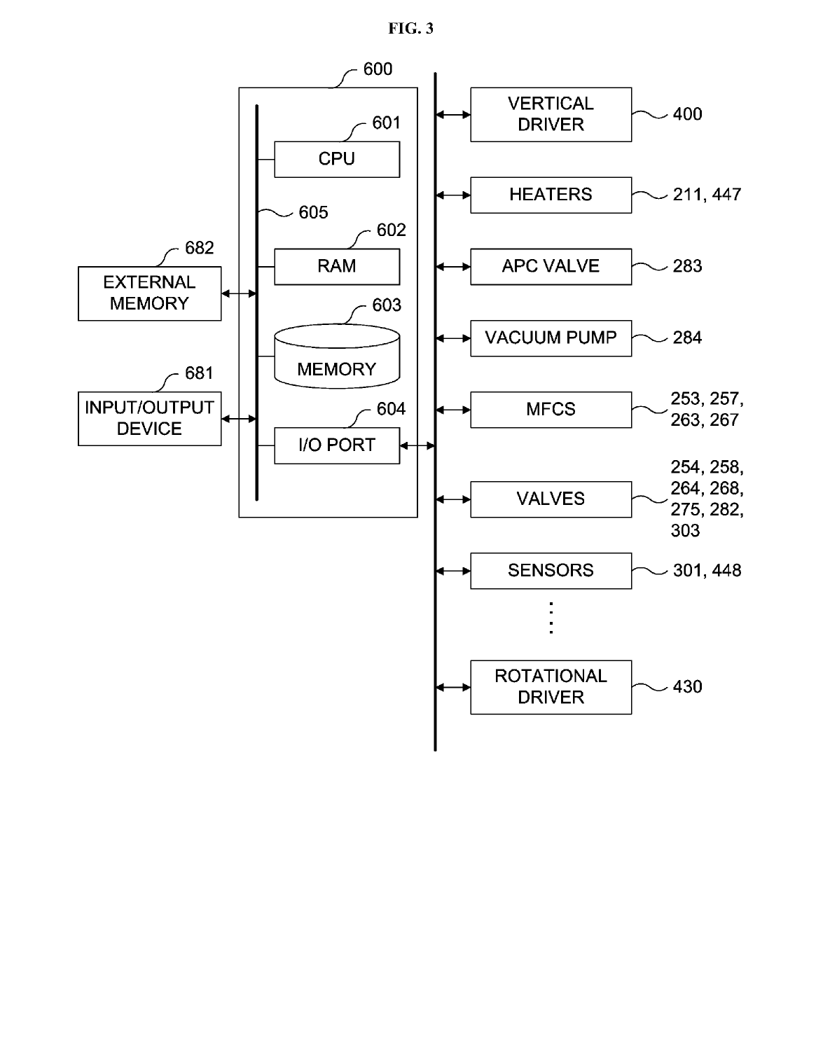

Subsequently, a controller 600 serving as a control structure (control apparatus) will be described with reference to FIG. 3. The substrate processing apparatus 10 includes the controller 600 configured to control operations of components constituting the substrate processing apparatus 10.

FIG. 3 is a diagram schematically illustrating a configuration of the controller 600. The controller 600 may be constituted by a computer including a CPU (Central Processing Unit) 601, a RAM (Random Access Memory) 602, a memory 603 serving as a memory structure and an I/O port (input/output port) 604. The RAM 602, the memory 603 and the I/O port 604 are configured to be capable of exchanging data with the CPU 601 via an internal bus 605.

For example, the memory 603 may be embodied by a component such as a flash memory and a HDD (Hard Disk Drive). For example, a control program for controlling an operation of the substrate processing apparatus 10 or a process recipe in which information such as procedures and conditions of the substrate processing is stored may be readably stored in the memory 603.

The process recipe is obtained by combining steps (procedures) of the substrate processing described later to obtain a predetermined result by performing the steps of the substrate processing described later by the controller 600, and acts as a program. Hereinafter, the process recipe and the control program may be collectively or individually referred to simply as a “program”. Thus, in the present specification, the term “program” may refer to the process recipe alone, may refer to the control program alone, or may refer to both of the process recipe and the control program. The RAM 602 serves as a memory area (work area) in which the program or the data read by the CPU 601 are temporarily stored.

The I/O port 604 is electrically connected to the components of the substrate processing apparatus 10 described above, such as the vertical driver 400, the heaters 211 and 447, the APC valve 283, the vacuum pump 284, the MFCs 253, 257, 263 and 267, the valves 254, 258, 264, 268, 275, 282 and 303, the sensors 301 and 448, and the rotational driver 430.

The CPU 601 is configured to read and execute the control program from the memory 603, and is configured to read the process recipe from the memory 603 in accordance with an instruction such as an operation command inputted from an input/output device 681. In accordance with contents of the process recipe read from the memory 603, the CPU 601 may be configured to be capable of controlling various operations such as an operation of elevating and lowering the substrate support 300 by the vertical driver 400, a heating operation by the heater 211, an operation of adjusting the opening degree of the APC valve 283, a start and stop operation of the vacuum pump 284, flow rate adjusting operations for various gases by the MFCs 253, 257, 263 and 267, opening and closing operations of the valves 254, 258, 264, 268, 275, 282 and 303, an operation of measuring the inner pressure of the tank 259 by the sensor 301, an operation of measuring the inner temperature of the tank 259 and/or the temperature of the gas stored in the tank 259 by the sensor 448, an operation of controlling the inner temperature of the tank 259 and/or the temperature of the gas stored in the tank 259 by the heater 447, and an operation of adjusting a rotation and a rotation speed of the substrate support 300 by the rotational driver 430. For example, the MFCs 253, 257, 263 and 267, the valves 254, 258, 264, 268, 275, 282 and 303, the APC valve 283 and the vacuum pump 284 may be used as a gas controller configured to be capable of controlling a supply and an exhaust of the gas into and out of the process chamber 201.

For example, the controller 600 according to the present embodiments may be embodied by preparing an external memory 682 (for example, a magnetic disk such as a hard disk, an optical disk such as a DVD, a magneto-optical disk such as an MO, a semiconductor memory such as a USB memory) storing the program described above and by installing the program onto the computer by using the external memory 682. In addition, a method of providing the program to the computer is not limited to a method using the external memory 682. For example, the program may be directly provided to the computer by a communication interface such as the Internet and a dedicated line instead of the external memory 682. In addition, the memory 603 and the external memory 682 may be embodied by a non-transitory computer-readable recording medium. Hereinafter, the memory 603 and the external memory 682 may be collectively or individually referred to as a “recording medium”. Thus, in the present specification, the term “recording medium” may refer to the memory 603 alone, may refer to the external memory 682 alone, or may refer to both of the memory 603 and the external memory 682.

### (2) Substrate Processing

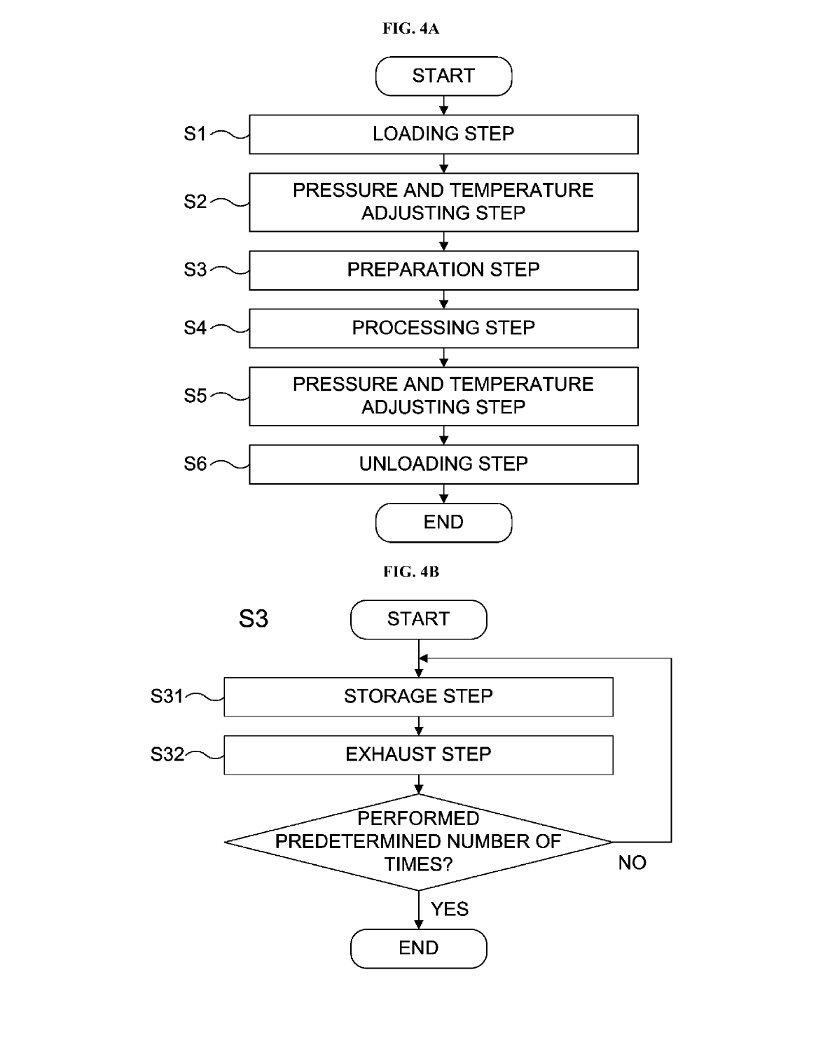

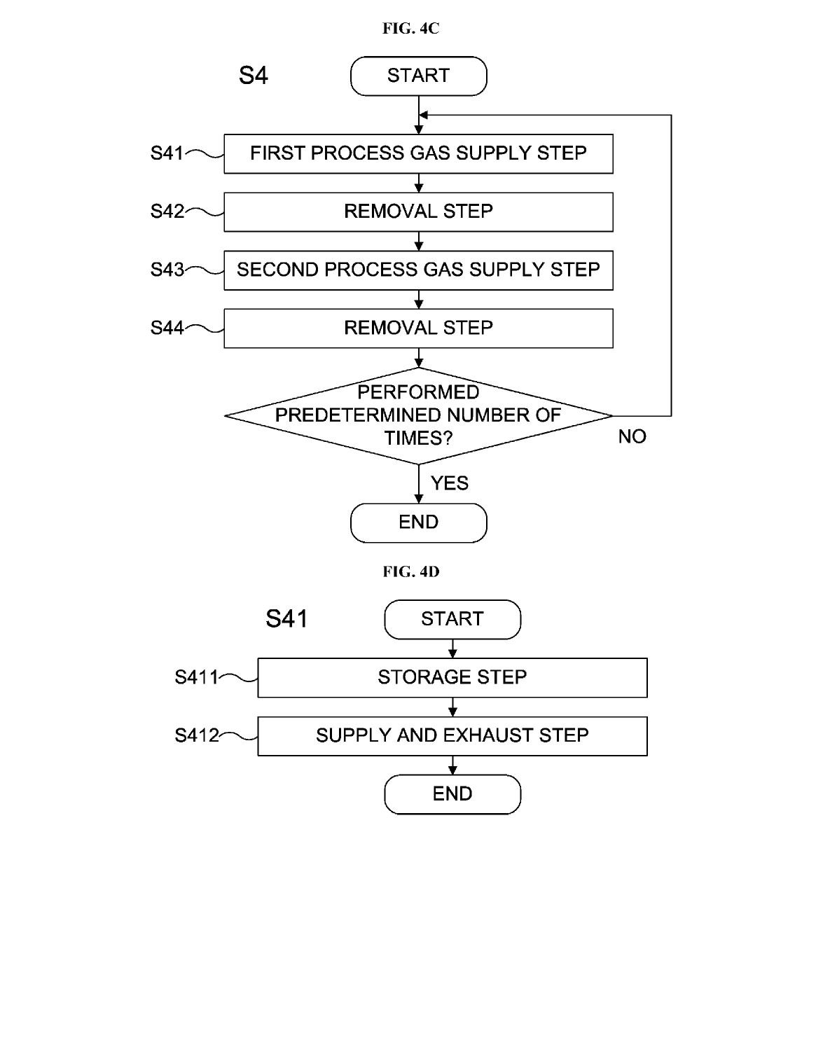

Hereinafter, as a part of a manufacturing process of a semiconductor device, the substrate processing will be described by way of an example in which a process (that is, a film forming process) of forming a film on the substrate S is performed by using the substrate processing apparatus 10 described above. The substrate processing will be described with reference to FIGS. 4A-4D. As shown in FIG. 4A, in the substrate processing, a loading step S1, a pressure and temperature adjusting step S2, a preparation step S3, a processing step S4, a pressure and temperature adjusting step S5 and an unloading step S6 are performed. In addition, in the following description, the controller 600 controls operations of the components constituting the substrate processing apparatus 10.

The substrate processing will be described by way of an example in which the substrate S with a concave structure (recess) (that is, a three-dimensional structure) such as a trench, a groove and a hole formed on a surface of the substrate S is used. In addition, in the present specification, the term “recess” is not limited to a structure provided with a bottom surface (lower surface), and may include a structure such as a through-hole and a gap provided without a bottom surface. When the structure is not provided with a bottom surface, the term “bottom side” may refer to a direction (side) from each of two or more openings of the structure toward an interior of the structure when viewed from each of the two or more openings.

In the present specification, the term “substrate” may refer to “a substrate itself”, or may refer to “a substrate and a stacked structure (aggregated structure) of a predetermined layer (or layers) or a film (or films) formed on a surface of the substrate”. In the present specification, the term “a surface of a substrate” may refer to “a surface of a substrate itself”, or may refer to “a surface of a predetermined layer (or a predetermined film) formed on a substrate”. Thus, in the present specification, “forming a predetermined layer (or a film) on a substrate” may refer to “forming a predetermined layer (or a film) directly on a surface of a substrate itself”, or may refer to “forming a predetermined layer (or a film) on a surface of another layer (or another film) formed on a substrate”. In the present specification, the terms “wafer” and “substrate” may be used as substantially the same meaning.

### Loading Step S1

In the transfer chamber 217, the substrates S are loaded (transferred) into the substrate support 300 (wafer charging step). Then, by elevating the substrate support 300 by the vertical driver 400, the substrates S are loaded into the reaction tube 210, that is, the process chamber 201 (boat loading step).

### Pressure and Temperature Adjusting Step S2

The opening degree of the APC valve 283 is adjusted and the process chamber 201 is exhausted by the vacuum pump 284 such that a pressure (inner pressure) of the process chamber 201 reaches and is maintained at a desired pressure (pressure adjusting step). In addition, an output of the heater 211 is controlled such that a temperature (inner temperature) of the process chamber 201 or a temperature of the substrate S can reach and be maintained at a desired temperature (process chamber temperature adjusting step). That is, in the pressure and temperature adjusting step S2, one or more among the inner temperature and the inner pressure of the process chamber 201 can be adjusted. In addition, the rotational driver 430 rotates the substrate support 300 (and the substrates S) and the partition plate support 310. In addition, the tank 259 is heated by the heater 447 such that the inner temperature of the tank 259 and the temperature of the gas stored in the tank 259 can reach and be maintained at a desired temperature (tank temperature adjusting step). In addition, the temperature of the first process gas supplier 250 is controlled such that the temperature of the gas supplied from the first process gas supply source 252 into the tank 259 is set to be lower than the inner temperature of the tank 259 or the temperature of the gas stored in the tank 259. As a result, it is possible to prevent particles from being generated in the tank 259 due to a liquefaction or solidification of a part of the first process gas. In addition, an output of the heater 447 is controlled such that the inner temperature of the tank 259 measured by the sensor 448 reaches and is maintained at a predetermined temperature (tank temperature adjusting step). Such operations mentioned above are continuously performed until at least a processing of the substrate S is completed.

### Preparation Step S3

In the preparation step S3, the predetermined gas in the first process gas supplier 250 is exhausted through the exhaust pipe 302 while blocking the flow of the gas from the exhaust pipe 281 to the process chamber 201. In the following description, the preparation step S3 will be described by way of an example in which a cycle including a storage step S31 and an exhaust step S32 is performed a predetermined number of times.

### Storage Step S31

In the storage step S31, the first process gas serving as the predetermined gas is stored in the tank 259. The valves 254, 258, 303, 264 and 268 are closed, and the valve 275 is opened. This starts storing the first process gas in the tank 259. Then, by closing the valve 275 after a predetermined time has elapsed, the storage step S31 is terminated (ended or completed). In addition, in the present specification, the term “supplying the gas into the tank 259 while the gas remains therein” may be referred to as “storing the gas in the tank 259”.

Hereinafter, the term “flow rate of the gas stored in the tank 259 in a certain step” may be referred to as a “storage flow rate in a certain step”. In addition, the term “time during which the gas is continuously stored in the tank 259 in a certain step” may be referred to as a “storage time in a certain step”. In addition, for example, an amount of the gas stored in the tank 259 in a certain step can be controlled by adjusting the storage flow rate and/or the storage time in such a step. In addition, for example, an amount of the gas remaining in the tank 259 at an end of a certain step can be controlled by adjusting the storage flow rate and/or the storage time in such a step.

### Exhaust Step S32

In the exhaust step S32, the first process gas stored in the tank 259 is exhausted from the tank 259 through the exhaust pipe 302 while blocking the flow of the gas from the exhaust pipe 281 to the process chamber 201. Specifically, by closing the valve 282, it is possible to block the flow of the gas from the exhaust pipe 281 to the process chamber 201. In such a state, by closing the valves 254, 275, 258, 264 and 268 and opening the valve 303, the first process gas is exhausted from the tank 259 through the exhaust pipe 302. Then, by closing the valve 303 after a predetermined time has elapsed, an exhaust of the first process gas from the tank 259 is terminated.

### Performing Cycle Predetermined Number of Times

The cycle including the storage step S31 and the exhaust step S32 is performed the predetermined number of times (n1 times, n1 is an integer of 1 or more). For example, it is preferable to perform the cycle a plurality number of times.

### Processing Step S4

In the processing step S4, the process gas (for example, the first process gas and the second process gas) is supplied to the substrate S arranged in the process chamber 201 through the supplier, and the gas in the process chamber 201 is exhausted through the exhaust pipe 281. In the following description, as shown in FIG. 4C, the present embodiments will be described by way of an example in which, as the processing step S4, a cycle including a first process gas supply step S41, a removal step S42, a second process gas supply step S43 and a removal step S44 is performed a plurality number of times (n times, where n is an integer of 2 or more) to form the film on the substrate S. In the following description, for example, the term “storage step S411 in a first execution (run) of the cycle” may also be referred to as a “first execution of the storage step S411”. The same also applies to other steps described in the present specification.

### First Process Gas Supply Step S41

In the first process gas supply step S41, the first process gas is supplied to the substrate S arranged in the process chamber 201 through the supplier. In the first process gas supply step S41, as shown in FIG. 4D, the storage step S411 and a supply step (also referred to as a “supply and exhaust step”) S412 are performed.

### Storage step S411

In the storage step S411, the first process gas is stored in the tank 259. The valves 254, 258, 303, 264 and 268 are closed, and the valve 275 is opened. This starts storing the first process gas in the tank 259. Then, by closing the valve 275 after a predetermined time has elapsed, the storage step S411 is terminated.

For example, a first execution of the storage step S411 may be performed simultaneously with one or more among the loading step S1 and the pressure and temperature adjusting step S2. In such a case, it is possible to shorten a time for the substrate processing.

### Supply Step S412

In the supply step (supply and exhaust step) S412, at least a part of the first process gas stored in the tank 259 is supplied to the substrate S arranged in the process chamber 201. By closing the valves 258, 275, 303, 264 and 268 and opening the valve 254, the supply step S412 is started. When the first process gas is supplied to the substrate S, a first layer constituted by at least a part of a molecular structure of the first process gas is formed.

In the supply step S412, it is preferable to open the valve 282 and the APC valve 283 and to exhaust the gas in the process chamber 201 through the exhaust pipe 281. As a result, since a flow velocity of the first process gas in the process chamber 201 can be increased, it is possible to suppress a decomposition of the first process gas. Then, by closing the valve 254 after a predetermined time has elapsed, the supply step S412 is terminated.

In the supply step S412, the first process gas stored in the tank 259 serving as the storage is supplied into the process chamber 201 in a short period of time. Thereby, it is possible to easily increase a partial pressure of the first process gas in the process chamber 201. As a result, since a sufficient amount of the first process gas can be easily supplied to a location which is difficult for the gas to reach such as a deep location (deep portion) of the recess, it is possible to easily process the entire surface of the substrate S sufficiently and uniformly. In addition, in the supply step S412, since the first process gas stored in the tank 259 is supplied into the process chamber 201 in a short period of time, it is possible to easily increase the flow velocity of the first process gas in the process chamber 201. Decomposition products generated by a thermal decomposition of the first process gas are more reactive than the first process gas and are more likely to be adsorbed at or near an opening of the recess. By increasing the flow velocity of the first process gas in the process chamber 201, it is possible to easily supply the first process gas in an undecomposed state to the entire surface of the substrate S. As a result, it is possible to easily process the entire surface of the substrate S sufficiently and uniformly.

For example, in the supply step S412, the valve 258 may be opened to supply the inert gas into the gas supply pipe 251 through the gas supply pipe 255. In addition, to prevent the first process gas from entering the gas supply pipe 261, the valves 268 and 264 may be opened to supply the inert gas into the gas supply pipe 261. At a start of the supply step S412, it is preferable to vacuum-exhaust the process chamber 201. As a result, since a pressure difference between the tank 259 (serving as the storage) and the process chamber 201 can be increased, it is possible to easily increase the flow velocity of the first process gas in the process chamber 201.

Hereinafter, the term “flow rate of the gas supplied from the tank 259 to a target such as the substrate S and the process chamber 201 in a certain step” may be referred to as a “supply flow rate in a certain step”. In addition, the term “time during which the gas is continuously supplied from the tank 259 to a target such as the substrate S and the process chamber 201 in a certain step” may be referred to as a “supply time in a certain step”. In addition, for example, an amount of the gas supplied from the tank 259 to a target such as the substrate S and the process chamber 201 in a certain step can be controlled by adjusting the supply flow rate and/or the supply time in such a step. In addition, for example, the amount of the gas remaining in the tank 259 at an end of a certain step can be controlled by adjusting the supply flow rate and/or the supply time in such a step.

As the first process gas, for example, a predetermined element-containing gas containing a predetermined element such as tungsten (W), titanium (Ti), molybdenum (Mo), tantalum (Ta), cobalt (Co), yttrium (Y), ruthenium (Ru), hafnium (Hf), zirconium (Zr), aluminum (Al) and silicon (Si) may be used. In such a case, as the first layer, it is possible to form a layer containing the predetermined element on the substrate S. As the first process gas, for example, one or more of the gases exemplified above may be used. As the first process gas, for example, a gas obtained by activating one or more of the gases exemplified above using a plasma and the like may also be used.

As the predetermined element-containing gas, for example, a halogen-based predetermined element-containing gas containing the predetermined element and a halogen element may be used. As the halogen-based predetermined element-containing gas, for example, a gas such as hexachlorotungsten (WCl₆), hexafluorotungsten (WF₆), titanium tetrachloride (TiCl₄), titanium tetrafluoride (TiF₄), molybdenum pentachloride (MoCl₅), molybdenum pentafluoride (MoF₅), molybdenum dioxide dichloride (MoO₂Cl₂), molybdenum oxide tetrachloride (MoOCl₄), tantalum pentachloride (TaCl₅), tantalum pentafluoride (TaF₅), cobalt difluoride (CoF₂), cobalt dichloride (CoCl₂), yttrium trifluoride (YF₃), yttrium trichloride (YCl₃), ruthenium trichloride (RuCl₃), ruthenium trifluoride (RuF₃), hafnium tetrachloride (HfCl₄), hafnium tetrafluoride (HfF₄), zirconium tetrachloride (ZrCl₄), zirconium tetrafluoride (ZrF₄), aluminum trichloride (AlCl₃), aluminum trifluoride (AlF₃), dichlorosilane (SiH₂Cl₂), 1,2-dichlorodisilane (Si₂H₄Cl₂), 1,1,1-trichlorodisilane (Si₂H₃Cl₃), 1,1,2-trichlorodisilane (Si₂H₃Cl₃), pentachlorodisilane (Si₂HCl₅), hexachlorodisilane (Si₂Cl₆), and tetrafluorosilane (SiF₄) may be used. As the predetermined element-containing gas, for example, a gas containing monosilane (SiH₄), disilane (Si₂H₆), trisilane (Si₃H₈), tetrasilane (Si₄H₁₀) or the like may be used. As the predetermined element-containing gas, for example, one or more of the gases exemplified above may be used.

As the predetermined element-containing gas, for example, an organic-based predetermined element-containing gas containing the predetermined element and an organic ligand may be used. As the organic-based predetermined element-containing gas, for example, a gas such as hexadimethyl aminoditungsten (W₂[N(CH₃)₂]₆), bistertiarybutylimino bisdimethylamino tungsten ((tBuN)₂(NMe₂)₂W), tetrakisethylmethylamino titanium (Ti[N(C₂H₅)(CH₃)]₄), bisethylcyclopentadienyl ruthenium (Ru(EtCp)₂), biscyclopentadienyl ruthenium (Ru(Cp)₂), tetrakisethylmethylamino hafnium (Hf[N(Me)Et]₄), tetrakisdiethylamino hafnium (Hf[N(Et)₂]₄), tetrakisdimethylamino hafnium (Hf[N(Me)₂]₄), trisdimethylaminocyclopentadienyl hafnium ((Cp)Hf[N(Me)₂]₃), tetrakisethylmethylamino zirconium (Zr[N(Me)Cp]₄), tetrakisdiethylamino zirconium (Zr[N(Et)₂]₄), tetrakisdimethylamino zirconium (Zr[N(Me)₂]₄), trisdimethylaminocyclopentadienyl zirconium ((Cp)Zr[N(Me)₂]₃), trimethyl aluminum (Al(CH₃)₃) and trisdimethylamino silane (Si[N(CH₃)₂]₃H) may be used. As the predetermined element-containing gas, for example, one or more of the gases exemplified above may be used.

### Removal Step S42

In the removal step S42, the process chamber 201 is vacuum-exhausted and/or purged. That is, the gas is exhausted from the process chamber 201 through the exhaust pipe 281. For example, the process chamber 201 is vacuum-exhausted by closing the valves 275, 303, 264, 254, 258 and 268 and exhausting the process chamber 201 by the vacuum pump 284. For example, the process chamber 201 is purged by closing the valves 275, 303 and 264 and opening the valves 254, 258 and 268 and supplying the inert gas serving as the purge gas into the process chamber 201 while exhausting the process chamber 201 by the vacuum pump 284. After a predetermined time has elapsed, the removal step S42 is terminated.

### Second Process Gas Supply Step S43

In the second process gas supply step S43, the second process gas is supplied to the substrate S arranged in the process chamber 201. By closing the valves 254, 258, 275, 303 and 268 and opening the valve 264, the second process gas supply step S43 is started. In such an operation, the valve 282 and the APC valve 283 are opened. Alternatively, the valves 258, 254 and 268 may be opened to supply the inert gas into the process chamber 201. Then, by closing the valve 264 after a predetermined time has elapsed, the second process gas supply step S43 is terminated. By supplying the second process gas to the substrate S, it is possible to modify the first layer on the substrate S to a second layer.

As the second process gas, for example, a gas such as a reducing gas, an oxidizing gas, a nitriding gas, a sulfide gas, a selenide gas and a telluride gas may be used. As the second process gas, for example, one or more of the gases exemplified above may be used. As the second process gas, for example, a gas obtained by activating one or more of the gases exemplified above using the plasma and the like may also be used.

For example, when the predetermined element-containing gas is used as the first process gas and the reducing gas is used as the second process gas, it is possible to form a layer constituted by the predetermined element alone on the substrate S as the second layer. For example, when the predetermined element-containing gas is used as the first process gas and one among the oxidizing gas, the nitriding gas, the sulfide gas, the selenide gas and the telluride gas is used as the second process gas, as the second layer formed on the substrate S, it is possible to form an oxide layer of the predetermined element, a nitride layer of the predetermined element, a sulfide layer of the predetermined element, a selenide layer of the predetermined element, or a telluride layer of the predetermined element.

As the reducing gas, for example, a gas such as hydrogen (H₂) gas, deuterium (D₂) gas, borane (BH₃) gas, diborane (B₂H₆) gas, carbon monoxide (CO) gas, ammonia (NH₃) gas, monosilane (SiH₄) gas, disilane (Si₂H₆) gas, trisilane (Si₃H₈) gas, monogermane (GeH₄) gas and digermane (Ge₂H₆) gas may be used. As the reducing gas, for example, one or more of the gases exemplified above may be used. In addition, as the reactive gas, for example, the oxidizing gas containing oxygen (O) may be used. As the oxidizing gas, for example, a gas such as oxygen (O₂) gas, ozone (O₃) gas, water vapor (H₂O), a gaseous mixture of the H₂ gas and the O₂ gas, hydrogen peroxide (H₂O₂) gas and nitrous oxide (N₂O) gas may be used. As the oxidizing gas, for example, one or more of the gases exemplified above may be used. As the nitriding gas, for example, a hydrogen nitride gas such as ammonia (NH₃) gas, diazene (N₂H₂) gas, hydrazine (N₂H₄) gas and N₃H₈ gas may be used. As the nitriding gas, for example, one or more of the gases exemplified above may be used. As the sulfide gas, for example, a gas such as sulfane (H₂S) gas, disulfane (H₂S₂) gas, diammonium sulfide ((NH₄)₂S) gas and dimethyl sulfide ((CH₃)₂S) gas may be used. As the sulfide gas, for example, one or more of the gases exemplified above may be used. As the selenide gas, for example, a gas such as selane (H₂Se) gas, diselane (H₂Se₂) gas and dimethyl selane ((CH₃)₂Se) gas may be used. As the selenide gas, for example, one or more of the gases exemplified above may be used. As the telluride gas, for example, a gas such as tellane (H₂Te) gas, ditellane (H₂Te₂) gas and dimethyl tellane ((CH₃)₂Te) gas may be used. As the telluride gas, for example, one or more of the gases exemplified above may be used.

### Removal Step S44

In the removal step S44, the process chamber 201 is vacuum-exhausted and/or purged, that is, the gas in the process chamber 201 is removed. The removal step S44 is started and ended in substantially the same manner as the removal step S42 described above.

### Performing Cycle Predetermined Number of Times

The cycle including the first process gas supply step S41, the removal step S42, the second process gas supply step S43 and the removal step S44 is performed a predetermined number of times (n2 times, where n2 is an integer of 1 or more). As a result, it is possible to form the film of a predetermined thickness constituted by one or more second layers on the substrate S. As the film formed on the substrate S, for example, it is possible to form a film constituted by the predetermined element alone, an oxide film of the predetermined element, a nitride film of the predetermined element, a sulfide film of the predetermined element, a selenide film of the predetermined element, or a telluride film of the predetermined element.

For example, in a second and subsequent executions of the cycle in the first process gas supply step S41, one or more among the removal step S42, the second process gas supply step S43 and the removal step S44 may be performed partially simultaneously with the storage step S411. As a result, it is possible to improve a throughput.

### Pressure and Temperature Adjusting Step S5

The inert gas serving as the purge gas is supplied into the process chamber 201, and is exhausted through the exhaust pipe 281. As a result, it is possible to remove a substance such as a residual gas and reaction by-products remaining in the process chamber 201 from the process chamber 201. Thereafter, an inner atmosphere of the process chamber 201 is replaced with the inert gas, and the inner pressure of the process chamber 201 is returned to the normal pressure (atmospheric pressure) (returning to atmospheric pressure step). In addition, the output of the heater 211 is controlled such that the inner temperature of the process chamber 201 can reach and be maintained at a desired temperature (temperature adjusting step).

### Unloading Step S6

The base flange 401 is lowered by the vertical driver 400, and the lower end of the reaction tube 210 is opened. Then, the substrates S (which are processed) are unloaded from the process chamber 201 into the transfer chamber 217 while supported by the substrate support 300 (boat unloading step). Then, the processed substrates S are taken out from the substrate support 300 in the transfer chamber 217 (wafer discharging step).

According to the present embodiments, in addition to effects mentioned above, it is possible to obtain one or more of the following effects.

(a) It is possible to remove the particles from the first process gas supplier 250 by exhausting the gas supplied into the supplier through the exhaust pipe 302. However, the gas introduced into the exhaust pipe 281 (along with the particles generated in the first process gas supplier 250 or the particles derived from deposits within the exhaust pipe 281) may enter the process chamber 201 through the exhaust pipe 281 and adhere to the substrate S.

In addition to such a case where the particles having entered the process chamber 201 along with the gas directly adhere to the substrate S, the particles having entered the process chamber 201 in advance may also adhere to the substrate S loaded into the process chamber 201. In the present disclosure, unless otherwise specified, at least one of the cases mentioned above may be referred to as an “adhesion of the particles” to the substrate S.

In the exhaust step S32 according to the present embodiments, the first process gas serving as the predetermined gas supplied into the supplier is exhausted through the exhaust pipes 302 and 281 while blocking the flow of the gas from the exhaust pipe 281 into the process chamber 201. As a result, since it is possible to prevent the gas from entering the process chamber 201 from the exhaust pipe 281, it is possible to further suppress the adhesion of the particles to the substrate S.

(b) In the first process gas supply step S41 according to the present embodiments, the first process gas is stored in the tank 259 in the storage step S411, and the first process gas stored in the tank 259 is supplied to the substrate S in the supply step S412. In such a case, a large amount of the first process gas is exhausted from the tank 259 in a short period of time. As a result, due to such a flow of the first process gas, the particles are likely to be removed (or peeled off) from the inner wall of the tank 259. Therefore, the particles are likely to adhere to the substrate S.

In the preparation step S3 according to the present embodiments, the first process gas serving as the predetermined gas supplied into the tank 259 is exhausted from the tank 259 through the exhaust pipes 302 and 281 while blocking the flow of the gas from the exhaust pipe 281 into the process chamber 201. As a result, it is possible to remove the particles in the tank 259 while preventing (suppressing) the particles in the tank 259 from entering the process chamber 201. Thereby, even when the storage step S411 and the supply step S412 are performed, it is possible to effectively suppress the adhesion of the particles to the substrate S.

(c) Consider a case in which, as in the preparation step S3 according to the present embodiments, the first process gas serving as the predetermined gas is stored in the tank 259 in the storage step S31, and the first process gas stored in the tank 259 is exhausted from the tank 259 through the exhaust pipes 302 and 281 in the exhaust step S32. In such a case, it is possible to easily and more efficiently remove the particles in the tank 259 before the first process gas supply step S41 is started. However, since a large amount of the gas is supplied into the exhaust pipe 281 in a short period of time, the gas in the exhaust pipe 281 is more likely to enter the process chamber 201. That is, the particles are more likely to adhere to the substrate S.

In the preparation step S3 according to the present embodiments, the storage step S31 and the exhaust step S32 are performed while blocking the flow of the gas from the exhaust pipe 281 into the process chamber 201. As a result, it is possible to efficiently remove the particles in the tank 259 while preventing (suppressing) the gas in the exhaust pipe 281 from entering the process chamber 201. Thereby, it is possible to effectively suppress the adhesion of the particles to the substrate S.

(d) In the preparation step S3, it is preferable to perform the cycle including the storage step S31 and the exhaust step S32 a plurality number of times. As a result, since it is possible to easily and efficiently remove the particles in the tank 259, it is possible to further suppress the adhesion of the particles to the substrate S.

(e) According to the present embodiments, the gas obtained by vaporizing the liquid substance or the solid substance at the room temperature and the normal pressure is used as the first process gas. In such a case, the first process gas may be liquefied or solidified, and then may adhere to the substrate S as the particles in the first process gas supplier. According to the technique of the present disclosure, even in such a case, it is possible to remove the particles in the first process gas supplier. In addition, in such a case, since components in the first process gas supplier 250, such as the tank 259 and its surrounding components, are likely to be under a high pressure, the first process gas may be easily liquefied or solidified in a location (cold spot) whose temperature is lower than those of its surrounding locations. However, according to the technique of the present disclosure, even in such a case, it is possible to efficiently remove the particles in the first process gas supplier 250 and it is also possible to prevent the particles from entering the process chamber 201 through the exhaust pipe 281. Thereby, it is possible to effectively suppress the adhesion of the particles to the substrate S.

### Other Embodiments of Present Disclosure

The technique of the present disclosure is described in detail by way of the embodiments mentioned above. However, the technique of the present disclosure is not limited thereto. The technique of the present disclosure may be modified in various ways without departing from the scope thereof.

For example, the embodiments mentioned above are described by way of an example in which, in the exhaust step S32, the gas in the first process gas supplier 250 is exhausted through the exhaust pipe 302 while blocking the flow of the gas from the exhaust pipe 281 to the process chamber 201. However, the technique of the present disclosure is not limited thereto. For example, the gas in the supplier may be exhausted through the subsidiary exhaust path while suppressing (or restricting) the flow of the gas from the main exhaust path to the process chamber 201. For example, in the exhaust step S32, the gas in the first process gas supplier 250 may be exhausted through the exhaust pipe 302 while the valves 254, 258 and 268 are opened to supply a large amount of the purge gas into the process chamber 201. In such a case, since a flow of the purge gas from the process chamber 201 to the vacuum pump 284 suppresses the flow of the gas from the main exhaust path to the process chamber 201, it is difficult for the particles to enter the process chamber 201. Thereby, it is possible to suppress the adhesion of the particles to the substrate S. In such a case, the first inert gas supplier and the second inert gas supplier may serve as an example of a predetermined structure configured to suppress or block the flow of the gas from the main exhaust path to the process chamber 201.

For example, the embodiments mentioned above are described by way of an example in which, in the first process gas supply step S41, the first process gas is stored in the tank 259 in the storage step S411 and the first process gas stored in the tank 259 is supplied to the substrate S in the supply step S412. However, the technique of the present disclosure is not limited thereto. For example, even when the first process gas supplier 250 does not include the tank 259, it is possible to obtain at least some of the effects mentioned above.

For example, the embodiments mentioned above are described by way of an example in which, in the preparation step S3, the first process gas serving as the predetermined gas is stored in the tank 259 in the storage step S31 and the first process gas stored in the tank 259 is exhausted through the exhaust pipe 302 in the exhaust step S32. However, the technique of the present disclosure is not limited thereto. For example, in the preparation step S3, the predetermined gas supplied into the tank 259 may be exhausted without being stored in the tank 259. Specifically, for example, in the preparation step S3, the valves 254, 258, 264 and 268 may be closed and the valves 275 and 303 may be opened. Even in such a case, it is possible to obtain at least some of the effects mentioned above.

For example, the embodiments mentioned above are described by way of an example in which, in the preparation step S3, the first process gas serving as the predetermined gas is used, that is, the predetermined gas is the same kind of gas as the process gas. However, the technique of the present disclosure is not limited thereto. For example, the predetermined gas may be a gas different from the process gas. As the predetermined gas, for example, the inert gas may be used. Even in such a case, it is possible to obtain at least some of the effects mentioned above.

At least a part of the preparation step S3 may be performed simultaneously with one or both of the loading step S1 and the pressure and temperature adjusting step S2. In such a case, it is possible to shorten the time for the substrate processing. In addition, the exhaust step S32 may be performed while the substrate S is present in the process chamber 201. In the exhaust step S32, the flow of the gas from the exhaust pipe 281 into the process chamber 201 is suppressed (restricted) or blocked. Therefore, even in such a case, it is possible to suppress the adhesion of the particles to the substrate S.

For example, the embodiments mentioned above are described by way of an example in which, in the preparation step S3, the predetermined gas in the first process gas supplier 250 (or the source gas supplier 250) is exhausted. However, the technique of the present disclosure is not limited thereto. For example, an additional exhaust pipe may be provided at the gas supply pipe 261 so as to connect the exhaust pipe 281 with a portion of the gas supply pipe 261 closer to the second process gas supply source 262 than the valve 264. Then, in the preparation step S3, the predetermined gas (for example, the second process gas or the purge gas) in the second process gas supplier 260 may be exhausted through the additional exhaust pipe. Even in such a case, it is possible to obtain at least some of the effects mentioned above.

For example, the embodiments mentioned above are described by way of an example in which the film is formed on the substrate S using the first process gas and the second process gas in the film forming process performed by the substrate processing apparatus 10. However, the technique of the present disclosure is not limited thereto. For example, the technique of the present disclosure may be preferably applied when three or more kinds of the process gases are used or when one kind of the process gas is used.

For example, the embodiments and modified examples mentioned above are described by way of an example in which a batch type substrate processing apparatus capable of simultaneously processing a plurality of substrates is used to form the film. However, the technique of the present disclosure is not limited thereto. For example, the technique of the present disclosure may be preferably applied when a single wafer type substrate processing apparatus capable of processing one or several substrates at once is used to form the film. For example, the embodiments and the modified examples mentioned above are described by way of an example in which a substrate processing apparatus including a hot wall type process furnace is used to form the film. However, the technique of the present disclosure is not limited thereto. For example, the technique of the present disclosure may be preferably applied when a substrate processing apparatus including a cold wall type process furnace is used to form the film. Even in such a case, it is possible to obtain substantially the same effects as in the embodiments or the modified examples mentioned above.

For example, the embodiments and the modified examples mentioned above may be appropriately combined. The process procedures and the process conditions of each combination thereof may be substantially the same as those of the embodiments or the modified examples mentioned above.

As described above, according to some embodiments of the present disclosure, it is possible to suppress the adhesion of the foreign matters (or the particles) to the substrate.

What is claimed is:

1. A substrate processing method comprising:
(a) performing:
(a1) supplying a process gas to a substrate arranged in a process chamber through a supplier; and
(a2) exhausting a gas in the process chamber through a main exhaust path configured to connect the process chamber to an exhaust apparatus; and
(b) exhausting a predetermined gas in the supplier through a subsidiary exhaust path configured to connect the supplier to the main exhaust path without passing through the process chamber, while suppressing or blocking a gas flow from the main exhaust path to the process chamber.

2. The substrate processing method of claim 1, wherein (a1) comprises:
(a11) storing the process gas in a storage provided in the supplier; and
(a12) supplying the process gas stored in the storage to the substrate, and
wherein, in (b), the predetermined gas supplied into the storage is exhausted through the subsidiary exhaust path while suppressing or blocking the gas flow from the main exhaust path to the process chamber.

3. The substrate processing method of claim 2, wherein (b) comprises:
(b1) storing the predetermined gas in the storage; and
(b2) exhausting the predetermined gas stored in the storage through the subsidiary exhaust path while suppressing or blocking the gas flow from the main exhaust path to the process chamber.

4. The substrate processing method of claim 1, wherein, in (b), the gas flow from the main exhaust path to the process chamber is blocked.

5. The substrate processing method of claim 1, wherein, in (b), the gas flow from the main exhaust path to the process chamber is suppressed.

6. The substrate processing method of claim 5, wherein, in (b), a purge gas in the process chamber is exhausted through the main exhaust path while the purge gas is supplied into the process chamber.

7. The substrate processing method of claim 1, wherein the predetermined gas is the same kind of gas as the process gas.

8. The substrate processing method of claim 1, wherein the predetermined gas is of a kind different from the process gas.

9. The substrate processing method of claim 8, wherein the predetermined gas is an inert gas.

10. The substrate processing method of claim 1, wherein a gas obtained by changing a phase of a liquid substance or a solid substance at a room temperature and a normal pressure is used as the process gas.

11. The substrate processing method of claim 1, wherein (b) is performed a plurality number of times before (a).

12. The substrate processing method of claim 1, wherein (b) is performed while the substrate is present in the process chamber.

13. A method of manufacturing a semiconductor device, comprising the method of claim 1.

14. A non-transitory computer-readable recording medium storing a program that causes a substrate processing apparatus, by a computer, to perform:
(a) performing:
(a1) supplying a process gas to a substrate arranged in a process chamber through a supplier; and
(a2) exhausting a gas in the process chamber through a main exhaust path configured to connect the process chamber to an exhaust apparatus; and
(b) exhausting a predetermined gas in the supplier through a subsidiary exhaust path configured to connect the supplier to the main exhaust path without passing through the process chamber, while suppressing or blocking a gas flow from the main exhaust path to the process chamber.

15. A substrate processing apparatus comprising:
a process chamber in which a substrate is arranged;
a main exhaust path configured to connect the process chamber to an exhaust apparatus;
a supplier configured to control a gas circulation between a supply source of a process gas, a supply source of a predetermined gas and the process chamber;
a subsidiary exhaust path configured to connect the supplier to the main exhaust path without passing through the process chamber;
an exhauster configured to control an exhaust of the gas through the main exhaust path and an exhaust of the gas through the subsidiary exhaust path;
a predetermined structure configured to suppress or block a gas flow from the main exhaust path to the process chamber; and
a controller configured to be capable of controlling the supplier, the exhauster and the predetermined structure so as to perform:
(a) performing:
(a1) supplying the process gas to the substrate through the supplier; and
(a2) exhausting the gas in the process chamber through the main exhaust path; and
(b) exhausting the predetermined gas in the supplier through the subsidiary exhaust path while suppressing or blocking the gas flow from the main exhaust path to the process chamber.
